(19) United States
(12) Patent Application Publication
(10) Pub. No.: US 2012/0167977 A1
(43) Pub. Date: Jul. 5, 2012

(54) SOLAR CELL AND METHOD FOR MANUFACTURING THE SAME

(76) Inventors: Jinhyung Lee, Seoul (KR); Junyong Ahn, Seoul (KR); Younghyun Lee, Seoul (KR)

(21) Appl. No.: 13/340,111

(22) Filed: Dec. 29, 2011

(30) Foreign Application Priority Data
Jan. 5, 2011 (KR) 10-2011-0000855

(51) Int. Cl. H01L 31/0224; H01L 31/18

(52) U.S. Cl. 136/256; 438/72; 257/E31.13; 257/E31.124

(57) ABSTRACT

A solar cell includes a substrate of a first conductive type, an emitter layer which is positioned at one surface of the substrate and has a second conductive type opposite the first conductive type, an anti-reflection layer which is positioned on the emitter layer and has a contact line, and an electrode part positioned on the emitter layer exposed by the contact line. The electrode part includes a seed layer directly contacting the emitter layer. The emitter layer has a first thickness of a formation area of the anti-reflection layer and a second thickness of a formation area of the seed layer. The first thickness is different from the second thickness.

This application claims priority to and the benefit of Korean Patent Application No. 10-2011-0000855 filed in the Korean Intellectual Property Office on Jan. 5, 2011, the contents of which are incorporated by reference in their entirety for all purposes as if fully set forth herein.

### BACKGROUND

1. Field of the Disclosure

Embodiments of the disclosure relate to a solar cell and a method for manufacturing the same.

2. Description of the Related Art

Recently, as existing energy sources such as petroleum and coal are expected to be depleted, interest in renewable energy for replacing the existing energy sources is increasing. As a renewable energy technology, solar cells for generating electric energy from solar energy have been particularly highlighted.

A solar cell generally includes a substrate and an emitter layer, which are formed of semiconductors of different conductive types, such as a p-type and an n-type, and electrodes respectively connected to the substrate and the emitter layer. A p-n junction is formed at an interface between the substrate and the emitter layer.

When light is incident on the solar cell having the above-described structure, electrons inside the semiconductors become free electrons (hereinafter referred to as ‘electrons’) by the photoelectric effect. Further, electrons and holes respectively move to the n-type semiconductor (for example, the emitter layer) and the p-type semiconductor (for example, the substrate) based on the principle of a p-n junction. The electrons and holes moving to the emitter layer and substrate are collected by the electrodes connected to the emitter layer and the substrate, respectively.

The technique for forming the electrodes electrically connected to the substrate and the emitter layer through a plating process has been recently developed.

### SUMMARY

In one aspect, there is a solar cell including a substrate of a first conductive type, an emitter layer at one surface of the substrate, the emitter layer having a second conductive type opposite the first conductive type, an anti-reflection layer on the emitter layer having an opening, a metal silicide seed layer formed on the emitter layer through the opening; and an electrode layer directly contacting the silicide seed layer.

The metal silicide seed layer may be formed of NiSi and may be formed in a portion of the surface of the emitter layer.

In another aspect, there is a solar cell including a substrate of a first conductive type, an emitter layer at one surface of the substrate, the emitter layer having a second conductive type opposite the first conductive type, an anti-reflection layer on the emitter layer, a contact line in the anti-reflection layer, an electrode part positioned on the emitter layer exposed by the contact line, the electrode part including a seed layer directly contacting the emitter layer, wherein the emitter layer has a first thickness at a formation area of the anti-reflection layer and a second thickness at a formation area of the seed layer, the first thickness being different from the second thickness.

The seed layer may be formed of nickel silicide with a thickness of about 50 nm to 200 nm.

In the emitter layer, the second thickness may be less than the first thickness.

A width of the seed layer is substantially equal to a width of each of the plurality of contact lines. The electrode part may further include an electrode layer on the seed layer.

The electrode layer may directly contact the seed layer. An upper width of the electrode layer may be greater than a width of each of the plurality of contact lines.

The electrode layer may include at least one selected from the group consisting of copper (Cu), silver (Ag), aluminum (Al), tin (Sn), zinc (Zn), indium (In), titanium (Ti), gold (Au), and a combination thereof.

In yet another aspect, there is a method for manufacturing a solar cell including forming an emitter layer of a second conductive type at one surface of a substrate of a first conductive type to a first thickness, forming an anti-reflection layer having a contact line on the emitter layer, forming a nickel layer inside the contact line, performing a thermal process to form a portion of the nickel layer contacting the emitter layer as a seed layer formed of nickel silicide, performing a selective etching process to remove the nickel layer remaining on the seed layer; and forming an electrode layer on the seed layer.

The forming of the seed layer may include forming the emitter layer in a formation area of the seed layer to a second thickness less than the first thickness of the emitter layer. Further, the forming of the seed layer includes performing the thermal process on the nickel layer at a temperature of about 400° C. to 500° C.

The removing of the nickel layer may include using H₂SO₄:H₂O₂ or HNO₃:CH₃COOH:H₂SO₄ in an etching solution.

According to the above-described characteristics, if the seed layer is formed between the emitter layer and the electrode layer, contact resistance may be reduced. Further, if the nickel layer between the electrode layer and the seed layer is removed, the electrode layer may directly contact the seed layer. As a result, a line resistance of the electrode part may be reduced.

### BRIEF DESCRIPTION OF THE DRAWINGS

The accompanying drawings, which are included to provide a further understanding of the disclosure and are incorporated in and constitute a part of this specification, illustrate embodiments of the invention and together with the description serve to explain the principles of the invention. In the drawings:

FIG. 1 is a partial cross-sectional view of a solar cell according to an exemplary embodiment of the invention;

FIG. 2 is an enlarged cross-sectional view of an electrode part shown in FIG. 1;

FIG. 3 is a graph illustrating changes in a line resistance depending on a thickness of a nickel layer; and

FIG. 4 sequentially illustrates a method for manufacturing a solar cell according to an exemplary embodiment of the invention.

### DETAILED DESCRIPTION OF THE EMBODIMENTS

Embodiments of the invention will be described more fully hereinafter with reference to the accompanying drawings, in which exemplary embodiments of the invention are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on other element, it may be on the entire surface of the other element and may not be on a portion of an edge of the other element.

Hereinafter, a solar cell and a method for manufacturing the same according to an exemplary embodiment of the invention are described with reference to the accompanying drawings.

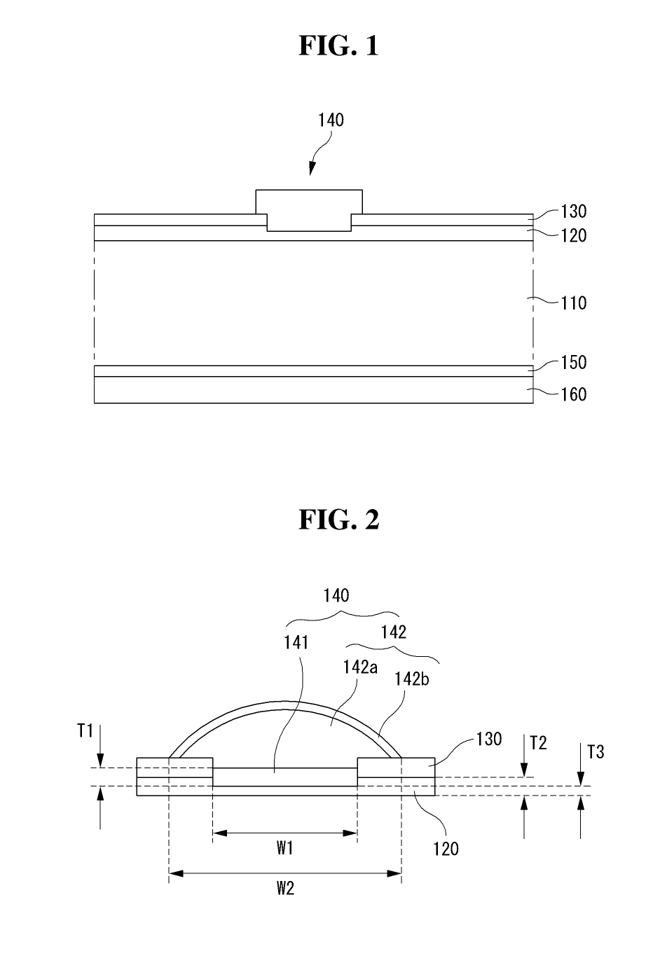

FIG. 1 is a partial cross-sectional view of a solar cell according to an exemplary embodiment of the invention. FIG. 2 is an enlarged cross-sectional view of an electrode part shown in FIG. 1.

As shown in FIGS. 1 and 2, a solar cell according to an exemplary embodiment of the invention includes a substrate 110, an emitter layer 120 positioned at one surface, for example, a front surface of the substrate 110, an anti-reflection layer 130 positioned on the emitter layer 120, a first electrode 140 positioned on the emitter layer 120 on which the anti-reflection layer 130 is not positioned, a back surface field (BSF) layer 150 positioned at a back surface of the substrate 110, and a second electrode 160 positioned on a back surface of the back surface field layer 150.

The substrate 110 may be formed of a silicon wafer of a first conductive type, for example, n-type, though not required. Silicon used in the substrate 110 may be single crystal silicon, polycrystalline silicon, or amorphous silicon. When the substrate 110 is of the n-type, the substrate 110 may contain impurities of a group V element such as phosphorus (P), arsenic (As), and antimony (Sb).

Alternatively, the substrate 110 may be p-type and/or be formed of semiconductor materials other than silicon. When the substrate 110 is p-type, the substrate 110 may contain impurities of a group III element such as boron (B), gallium (Ga), and indium (In).

At least one of the front surface and the back surface of the substrate 110 may be textured to form an uneven surface having non-uniform characteristics.

The emitter layer 120 positioned at the front surface of the substrate 110 may have an impurity region of a second conductive type (for example, p-type) opposite the first conductive type (for example, n-type) of the substrate 110 and form a p-n junction with the substrate 110.

A plurality of electron-hole pairs produced by light incident on the substrate 110 are separated into electrons and holes by a built-in potential difference resulting from the p-n junction between the substrate 110 and the emitter layer 120. The separated electrons move to the n-type semiconductor, and the separated holes move to the p-type semiconductor. Thus, when the substrate 110 is n-type and the emitter layer 120 is p-type, the separated electrons and the separated holes move to the substrate 110 and the emitter layer 120, respectively. Hence, the electrons become major carriers in the substrate 110, and the holes become major carriers in the emitter layer 120.

When the emitter layer 120 is p-type, the emitter layer 120 may be formed by doping the substrate 110 with impurities of a group III element such as boron (B), gallium (Ga), and indium (In).

Alternatively, when the substrate 110 is p-type, the emitter layer 120 may be n-type. In this instance, the separated holes move to the substrate 110, and the separated electrons move to the emitter layer 120.

When the emitter layer 120 is n-type, the emitter layer 120 may be formed by doping the substrate 110 with impurities of a group V element such as phosphorus (P), arsenic (As), and antimony (Sb).

The anti-reflection layer 130 on the emitter layer 120 may be positioned at a surface of the substrate 110 to reduce reflection of light which may be incident on the surface of the substrate 110 and increase selectivity of a predetermined wavelength band, thereby increasing the efficiency of the solar cell. The anti-reflection layer 130 may include at least one of a silicon oxide layer, a silicon nitride layer, a titanium dioxide layer, an aluminum oxide layer, and a silicon nitride-oxide layer.

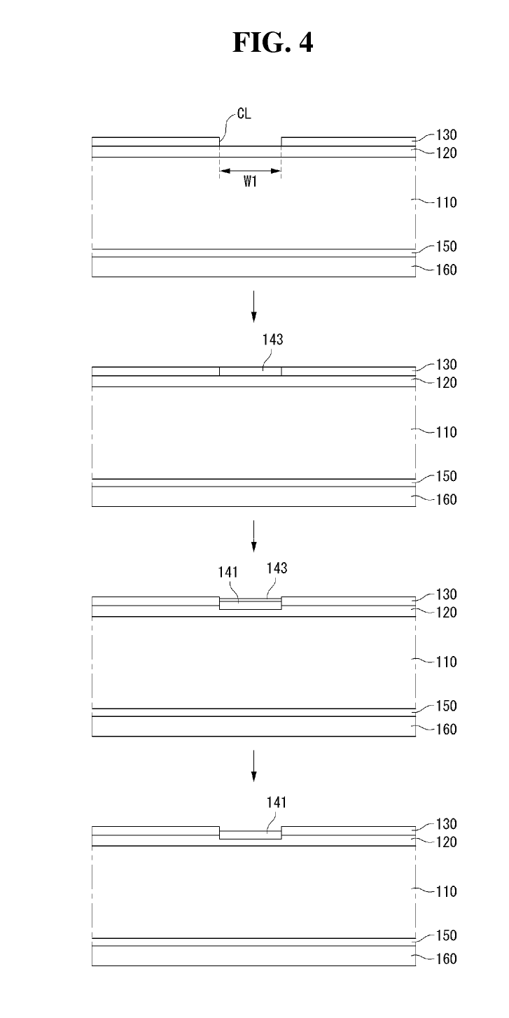

The anti-reflection layer 130 may include a plurality of contact lines CL (as seen in FIG. 4) exposing a portion of the emitter layer 120. The first electrode 140 may be formed on a portion of the emitter layer 120 that is exposed through the contact lines CL.

Each of the contact lines CL may have a predetermined width, for example, a width W1 of about 20 μm to 60 μm. When the contact line CL has the width W1, the first electrode 140 formed through a plating process may have a high aspect ratio, for example, an aspect ratio of about 0.83 to 1. In the embodiment of the invention, the aspect ratio is a ratio of width to thickness of the first electrode 140.

The first electrode 140 formed on the emitter layer 120 exposed through the contact lines CL may be electrically and physically connected to the emitter layer 120. The first electrode 140 may extend substantially parallel in a fixed direction.

The first electrode 140 collects carriers (for example, holes) moving to the emitter layer 120. In the embodiment of the invention, the first electrode 140 may be a finger electrode. Alternatively, the first electrode 140 may further include a finger electrode current collector as well as the finger electrode.

The first electrode 140 may include a seed layer 141 directly contacting the emitter layer 120 and an electrode layer 142 positioned on the seed layer 141. The seed layer 141 may be formed of a material containing nickel, for example, nickel silicide (including NiSi, Ni₂Si, NiSi₂, etc.) and may have a thickness T1 of about 50 nm to 200 nm.

When the thickness T1 of the seed layer 141 is less than about 50 nm, the electrode may have high contact resistance. When the thickness T1 of the seed layer 141 is greater than about 200 nm, a shunt leakage current may occur because of the distribution of nickel particles resulting in a thermal process used for forming the seed layer 141. Thus, when the thickness T1 of the seed layer 141 is about 50 nm to 200 nm, contact resistance may be reduced and shunt leakage current may be prevented.

The emitter layer 120 may have a first thickness T2 in an area adjacent to the anti-reflection layer 130 and a second thickness T3 in an area adjacent to the seed layer 141. Because the seed layer 141 may be positioned inside the contact line CL, the first and second thicknesses T2 and T3 of the emitter layer 120 are different from each other. Namely, the second thickness T3 may be less than the first thickness T2. The seed layer 141 in this configuration may have the same width W1 as the contact line CL.

The electrode layer 142 on the seed layer 141 may be formed of at least one conductive metal material. Examples of the conductive metal material include at least one selected from the group consisting of nickel (Ni), copper (Cu), silver (Ag), aluminum (Al), tin (Sn), zinc (Zn), indium (In), titanium (Ti), gold (Au), and a combination thereof. Other materials may also be used.

In the embodiment of the invention, the electrode layer 142 may include a copper layer 142a. The copper layer 142a substantially serves as an electrical conductor. However, it is known that copper easily oxidizes in air. Also, it is known that it is difficult to directly solder an interconnector, for example, a ribbon for electrically connecting the adjacent solar cells to the copper layer 142a used in module processing of the solar cells.

Thus, when the electrode layer 142 includes a copper layer 142a, the electrode layer 142 may further include a tin layer 142b on the copper layer 142a, so as to prevent the oxidization of copper and to facilitate soldering between the ribbon and the copper layer 142a.

An upper width W2 of the electrode layer 142 may be greater than the width W1 of the contact line CL. For this, the electrode layer 142 may be formed more thickly than the anti-reflection layer 130. For example, a thickness of the electrode layer 142 may be about 10 μm to 30 μm. The tin layer 142b may have a thickness of about 5 μm to 15 μm.

If the electrode layer 142 is formed of metal materials other than copper, for example, silver (Ag), the tin layer 142b may be omitted.

When the first electrode 140 is a finger electrode, a finger electrode current collector for collecting carriers moving to the finger electrode may be formed on the front surface of the substrate 110 in a direction crossing the finger electrode. The finger electrode current collector may be formed through a plating process in the same manner as the first electrode 140. Alternatively, unlike the finger electrode, the finger electrode current collector may be formed by printing, drying, and firing a conductive paste containing a conductive material.

In the first electrode 140 having the above-described configuration, the electrode layer 142 may directly contact the seed layer 141. As a result, line resistance generated when the seed layer 141 and the electrode layer 142 directly contact each other without a nickel layer therebetween is less than the line resistance generated when a nickel layer is formed between the seed layer 141 and the electrode layer 142.

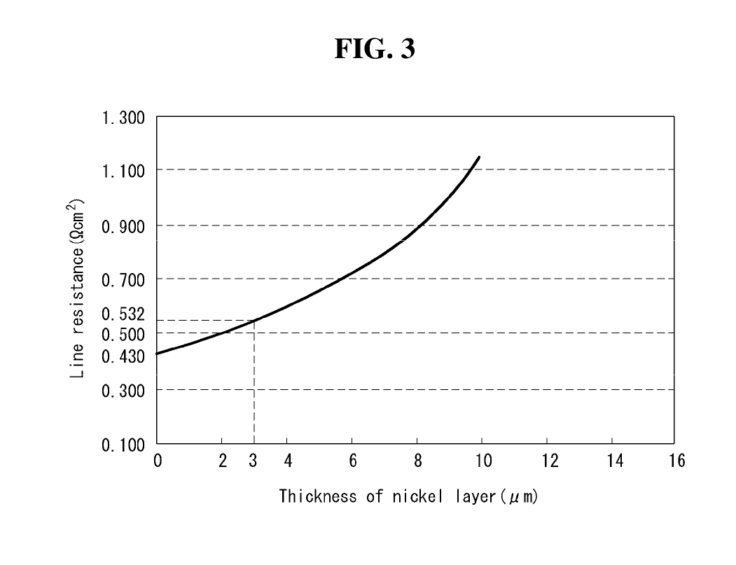

FIG. 3 is a graph illustrating line resistance as a function of nickel layer thickness. In the experimental configuration resulting in FIG. 3, the electrode layer 142 was formed of silver.

As shown in FIG. 3, when a cross-sectional area of the first electrode 140 was about 600 μm² a line resistance of the first electrode 140 not including the nickel layer was less than a line resistance of the first electrode 140 including the nickel layer.

For example, when there was no nickel layer between the seed layer 141 and the electrode layer 142, the line resistance of the first electrode 140 was measured at about 0.43 Ωcm². When the nickel layer having a thickness of about 3 μm is formed between the seed layer 141 and the electrode layer 142, the line resistance of the first electrode 140 was measured at about 0.532 Ωcm². Further, the line resistance of the first electrode 140 increased as the thickness of the nickel layer increased.

Accordingly, the solar cell in an embodiment of the invention in which the seed layer 141 and the electrode layer 142 directly contact each other may reduce line resistance more than when the nickel layer is formed between the seed layer 141 and the electrode layer 142.

Referring back to FIG. 1, the second electrode 160 positioned on the back surface of the substrate 110 collects carriers (for example, electrons) moving to the substrate 110 and outputs the carriers to an external device.

The second electrode 160 may be formed of at least one conductive material selected from the group consisting of aluminum (Al), nickel (Ni), copper (Cu), silver (Ag), tin (Sn), zinc (Zn), indium (In), titanium (Ti), gold (Au), and a combination thereof. Other materials may also be used.

The second electrode 160 may include a back electrode and a back electrode current collector. The back electrode current collector may be positioned in a direction parallel to a finger electrode current collector. The back electrode current collector may output carriers collected by the back electrode to an external device.

The back surface field layer 150 may be positioned at the entire back surface of the substrate 110 or in an area of the second electrode 160. The back surface field layer 150 is a region (for example, n⁺-type region) that is more heavily doped than the substrate 110 with impurities of the same conductive type as the substrate 110.

The movement of carriers to the back surface of the substrate 110 may be prevented or reduced by a potential barrier resulting from a difference between impurity concentrations of the substrate 110 and the back surface field layer 150. As a result, the recombination and/or disappearance of electrons and holes around the surface of the substrate 110 are prevented or reduced.

An operation of the solar cell having the above-described configuration is described below.

When light irradiated onto the solar cell is incident on the substrate 110 through the emitter layer 120, a plurality of electron-hole pairs are generated in the substrate 110 by absorbed light energy.

When the front surface of the substrate 110 is a textured surface, light reflectance in the front surface of the substrate 110 may be reduced. Hence, light absorption increases and the efficiency of the solar cell is improved.

In addition, because light reflection is reduced by the anti-reflection layer 130, an amount of light incident on the substrate 110 increases to further enhance light absorption of the solar cell.

The electron-hole pairs are separated into electrons and holes by the p-n junction between the substrate 110 and the emitter layer 120. The separated holes move to the p-type emitter layer 120 and the separated electrons move to the n-type substrate 110. The holes moving to the emitter layer 120 move to the first electrode 140, and the electrons moving to the substrate 110 move to the second electrode 160 through the back surface field layer 150.

Accordingly, when the first electrode 140 of one solar cell is connected to the second electrode 160 of an adjacent solar cell using an interconnector, electric current flows through the solar cells that can be used for electric power.

A method for manufacturing the solar cell according to the exemplary embodiment of the invention is described below with reference to FIG. 4.

FIG. 4 sequentially illustrates, from top to bottom, a method for manufacturing a solar cell according to an example embodiment of the invention.

As shown in FIG. 4, an emitter layer 120 having a first thickness T2 is formed at one surface, for example, a front surface of a substrate 110 of a first conductive type, and an anti-reflection layer 130 is formed on the emitter layer 120.

When the substrate 110 is n-type, the emitter layer 120 may be formed by doping the substrate 110 with impurities of a group III element such as boron (B), gallium (Ga), and indium (In).

Alternatively, when the substrate 110 is p-type, the emitter layer 120 may be formed by doping the substrate 110 with impurities of a group V element such as phosphorus (P), arsenic (As), and antimony (Sb).

Before the emitter layer 120 is formed, the one surface of the substrate 110 may be textured to form an uneven surface. A texturing process may be performed by immersing the substrate 110 in a bath filled with an alkali solution for a predetermined period of time. For example, the texturing process may be performed by immersing the substrate 110 in an alkali solution with a temperature of about 80° C. for about 20 to 40 minutes. As the texturing process progresses, the front surface of the substrate 110 is etched to form a plurality of uneven portions such as non-uniform structures.

Examples of the alkali solution include KOH solution of about 2 wt % to 5 wt % and NaOH solution of about 2 wt % to 5 wt %. In addition, a NH₄OH solution may be used.

The height of each of the uneven portions of the textured surface, i.e., a height of the structure may be about 1 μm to 10 μm.

After the emitter layer 120 is formed, the anti-reflection layer 130 may be formed on the emitter layer 120 using a chemical vapor deposition (CVD) method such as a plasma enhanced CVD (PECVD) method or sputtering. The anti-reflection layer 130 may be one of a silicon oxide layer, a silicon nitride layer, a titanium dioxide layer, an aluminum oxide layer, and a silicon nitride-oxide layer.

The anti-reflection layer 130 may have two layers each having different physical properties. In this instance, a lower layer of the two layers may be formed of a material having a high refractive index, and an upper layer may be formed of a material having a refractive index less than the refractive index of the lower layer.

After the anti-reflection layer 130 is formed, a second electrode 160 and a back surface field layer 150 may be formed at the other surface, for example, a back surface of the substrate 110.

Subsequently, the anti-reflection layer 130 may be patterned to form a plurality of contact lines CL each having a predetermined width W1. The anti-reflection layer 130 may be patterned through an etching process using laser ablation or an etching process using an etching paste or an etching resist.

Subsequently, a nickel layer 143 may be formed inside the contact line CL. The nickel layer 143 may be formed using a vacuum method, for example, a sputtering method. As another example, the nickel layer 143 may be formed through an electroless plating process or an electroplating process. Although it is not shown, the nickel layer 143 may be formed on the anti-reflection layer 130.

After the nickel layer 143 is formed, a thermal process may performed at a temperature of about 400° C. to 500° C. to form a seed layer 141 formed of nickel silicide (including NiSi, Ni₂Si, NiSi₂, etc.). The seed layer 141 may have a thickness T1 of about 50 nm to 200 nm to reduce contact resistance and to prevent shunt leakage current.

When the thermal process forming the seed layer 141 is performed, nickel contained in the nickel layer 143 is distributed into the emitter layer 120. Thus, the emitter layer 120 has a second thickness T3 in a formation area of the seed layer 141.

After the seed layer 141 is formed, a selective etching process may be performed to remove the nickel layer 143. In the embodiment of the invention, the selective etching process is an etching process for removing only one material among nickel silicide forming the seed layer 141 and nickel forming the nickel layer 143.

In the embodiment of the invention, H₂SO₄:H₂O₂ or HNO₃:CH₃COOH:H₂SO₄ is used in an etching solution to remove the nickel layer 143. Hence, a line resistance of the first electrode 140 may be reduced.

After the surface of the seed layer 141 is exposed by removing the nickel layer 143, an electrode layer 142 is formed on the seed layer 141. The electrode layer 142 may be formed by sequentially forming a copper layer 142a having a thickness of about 10 μm to 30 μm and a tin layer 142b having a thickness of about 5 μm to 15 μm through an electroplating process.

When the electrode layer 142 is formed, the copper layer 142a may be formed thicker than the anti-reflection layer 130. For example, the copper layer 142a may be formed to a thickness of about 10 μm to 30 μm, and the tin layer 142b formed following the copper layer 142a may have a thickness of about 5 μm to 15 μm. Thus, an upper width W2 of the electrode layer 142 is greater than the width W1 of the contact line CL.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a substrate of a first conductive type;
an emitter layer at one surface of the substrate, the emitter layer having a second conductive type opposite the first conductive type;
an anti-reflection layer on the emitter layer having an opening;
a metal silicide seed layer formed on the emitter layer through the opening; and
an electrode layer directly contacting the silicide seed layer.

2. The solar cell of claim 1, wherein the metal silicide seed layer is formed of NiSi.

3. The solar cell of claim 1, wherein an electrode is formed on a portion of a surface of the silicide seed layer.

4. The solar cell of claim 1, wherein at least a front surface or a back surface of the substrate is textured to form an uneven characteristic.

5. A solar cell comprising:
a substrate of a first conductive type;
an emitter layer at one surface of the substrate, the emitter layer having a second conductive type opposite the first conductive type;
an anti-reflection layer on the emitter layer;
a contact line in the anti-reflection layer;
an electrode part positioned on the emitter layer exposed by the contact line, the electrode part including a seed layer directly contacting the emitter layer,
wherein the emitter layer has a first thickness at a formation area of the anti-reflection layer and a second thickness at a formation area of the seed layer, the first thickness being different from the second thickness.

6. The solar cell of claim 4, wherein the seed layer is formed of nickel silicide.

7. The solar cell of claim 5, wherein the seed layer has a thickness of about 50 nm to 200 nm.

8. The solar cell of claim 4, wherein the second thickness is less than the first thickness.

9. The solar cell of claim 4, wherein a width of the seed layer is substantially equal to a width of the contact line.

10. The solar cell of claim 4, wherein the electrode part further includes an electrode layer on the seed layer.

11. The solar cell of claim 9, wherein the electrode layer directly contacts the seed layer.

12. The solar cell of claim 9, wherein an upper width of the electrode layer is greater than a width of the contact line.

13. The solar cell of claim 4, wherein a ratio of a width to a thickness of the electrode layer is about 0.83 to 1.

14. The solar cell of claim 9, wherein the electrode layer includes at least one selected from the group including copper (Cu), silver (Ag), aluminum (Al), tin (Sn), zinc (Zn), indium (In), titanium (Ti), gold (Au), and a combination thereof.

15. The solar cell of claim 4, wherein at least a front surface or a back surface of the substrate is textured to form an uneven characteristic.

16. The solar cell of claim 4, further comprising:
a back surface field layer; and
a second electrode on the back surface field layer.

17. A method for manufacturing a solar cell comprising:
forming an emitter layer of a second conductive type at one surface of a substrate of a first conductive type to a first thickness;
forming an anti-reflection layer having a contact line on the emitter layer;
forming a nickel layer inside the contact line;
performing a thermal process to form a portion of the nickel layer contacting the emitter layer as a seed layer formed of nickel silicide;
performing a selective etching process to remove the nickel layer remaining on the seed layer; and
forming an electrode layer on the seed layer.

18. The method of claim 13, wherein the forming of the seed layer includes forming the emitter layer in a formation area of the seed layer to a second thickness less than the first thickness of the emitter layer.

19. The method of claim 13, wherein the forming of the seed layer includes performing the thermal process on the nickel layer at a temperature of about 400° C. to 500° C.

20. The method of claim 13, wherein the removing of the nickel layer includes using H₂SO₄:H₂O₂ or HNO₃:CH₃COOH:H₂SO₄ in an etching solution.
